(19) United States
(12) Patent Application Publication
(10) Pub. No.: US 2026/0026272 A1
(43) Pub. Date: Jan. 22, 2026

(54) SUBSTRATE PROCESSING SYSTEM USING AN OPTICAL PATTERN

(71) Applicant: Tokyo Electron Limited, Tokyo (JP)

(72) Inventor: Ivan Maleev, Fremont, CA (US)

(21) Appl. No.: 18/774,713

(22) Filed: Jul. 16, 2024

(51) Int. Cl. H01L 21/3065

(52) U.S. Cl. CPC H10P 50/242

(57) ABSTRACT

A method for processing a substrate includes receiving the substrate on a substrate holder disposed in a processing chamber, and performing a cyclic process. One cycle of the cyclic process includes applying a first pulse to illuminate, from an optical source, an optical pattern over a surface of the substrate to locally heat portions of the surface of the substrate according to the optical pattern. And one cycle of the cyclic process further includes applying a second pulse to generate a processing beam to process the substrate with the optical pattern, the first pulse preceding the second pulse.

### TECHNICAL FIELD

The present invention relates generally to systems and methods of processing a substrate, and, in particular embodiments, to systems and methods of processing a substrate that use optical patterns to spatially control processing rates.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Process flows used to form the constituent structures of semiconductor devices often involve depositing and removing a variety of materials while a pattern of several materials may be exposed in a surface of the working substrate.

In the field of semiconductor fabrication, etching processes are utilized to selectively remove material from the surface of a semiconductor substrate. Etching can be achieved through various techniques such as wet etching, where chemical solutions are used, and dry etching, which typically involves plasma-based processes. A common goal in these processes is to achieve precise control over etch rate and uniformity, both of which are imperative for maintaining the integrity of the micro- and nano-scale features being fabricated on the semiconductor devices.

### SUMMARY

In accordance with an embodiment of this disclosure, a method for processing a substrate includes receiving the substrate on a substrate holder disposed in a processing chamber, and performing a cyclic process. One cycle of the cyclic process includes applying a first pulse to illuminate, from an optical source, an optical pattern over a surface of the substrate to locally heat portions of the surface of the substrate according to the optical pattern. And one cycle of the cyclic process further includes applying a second pulse to generate a processing beam to process the substrate with the optical pattern, the first pulse preceding the second pulse.

In accordance with another embodiment of this disclosure, a method for processing a substrate includes receiving the substrate on a substrate holder disposed in a processing chamber, and scanning, using an optical scanner, a raster pattern over a surface of the substrate, the optical scanner illuminating portions of the surface of the substrate as the optical scanner passes over to locally heat the portions according to an optical pattern. And the method further includes scanning, using a second scanner, the raster pattern over the surface of the substrate by following the optical scanner, the second scanner releasing materials over the surface of the substrate to process the substrate.

And in accordance with yet another embodiment of this disclosure, a system for processing a substrate includes a substrate holder disposed in a processing chamber, and an optical source optically coupled to the processing chamber. And the system further includes a controller coupled to the optical source, the substrate holder, the processing chamber, and a memory storing instructions to be executed in the controller. The instructions when executed cause the controller to receive the substrate on the substrate holder disposed in the processing chamber, and perform a cyclic process. One cycle of the cyclic process includes applying a first pulse to illuminate, from the optical source, an optical pattern over a surface of the substrate to locally heat portions of the surface of the substrate according to the optical pattern. And one cycle of the cyclic process further includes applying a second pulse to generate a processing beam to process the substrate with the optical pattern, the first pulse preceding the second pulse.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1B are schematic diagrams of a processing system for a stationary substrate in accordance with an embodiment of this disclosure;

FIG. 2 illustrates a chamber cover for a processing chamber in accordance with an embodiment of this disclosure;

FIG. 3 is a schematic diagram of an illuminator in accordance with an embodiment of this disclosure;

FIG. 4 illustrates an optical pattern which may be projected on a substrate by the illuminator in accordance with an embodiment of this disclosure;

FIGS. 5A-5B illustrate side views of the processing systems of FIGS. 1A-1B in accordance with an embodiment of this disclosure;

FIG. 6 is a flowchart of a processing method for a stationary substrate in accordance with an embodiment of this disclosure;

FIG. 7 is a schematic diagram of a processing system for a moving substrate in accordance with an embodiment of this disclosure;

FIG. 8 illustrates a raster pattern which may be traced using the processing system for the moving substrate of FIG. 7 in accordance with an embodiment of this disclosure;

FIG. 9 is a flowchart of a processing method for a moving substrate in accordance with an embodiment of this disclosure;

FIG. 10 is a schematic diagram of a plasma processing system capable of modulating plasma parameters in accordance with an embodiment of this disclosure;

FIG. 11 illustrates an optical pattern which may modulate plasma parameters above a substrate using the plasma processing system of FIG. 10 in accordance with an embodiment of this disclosure; and

FIG. 12 is a flowchart of a plasma processing method which may modulate plasma parameters in accordance with an embodiment of this disclosure.

### DETAILED DESCRIPTION OF ILLUSTRATIVE EMBODIMENTS

Processing rates can be influenced by several factors, including temperature, chemical concentration, and the physical properties of the materials used in processing a substrate (such as a plasma), if applicable. Traditionally, attempts to control the processing rate across a substrate surface involve global adjustments, such as modifying the overall temperature or changing the gas composition within the processing chamber. However, these methods do not allow for localized control and can be inadequate when dealing with substrates that have non-uniformities or patterns that require differential processing rates across the surface for proper feature development or compensation for known process variations.

More recently, localized or point plasma sources along with substrates on a moving stage were proposed. However, such systems are still limited by the size of a plasma spot on a sample (few millimeters) and the use of complex mechanical subsystems to rapidly move substrates with respect to the point plasma source.

To address these limitations, recent advancements have focused on achieving spatial resolution in the control parameters. These include employing localized heating elements, patterning of etch-resistant materials, and introducing localized processing beams targeted at specific regions of the substrate. Nevertheless, there exists a persistent desire for improved systems capable of dynamically modifying temperature distributions with high resolution over the substrate surface during processing.

Conventional systems lack sufficient control over localized temperature variations and often struggle with response times and granularity of control. As feature sizes on substrates continue to shrink and designs become more complex, achieving precise spatial control over processing is even more imperative, and increases a desire for improvements in localized temperature control strategies.

Moreover, existing solutions may not offer real-time adjustment capabilities or may use complex infrastructures that are not easily integrated into existing semiconductor processing workflows. Thus, an innovative approach that offers a high degree of resolution in temperature profiling, allows for real-time adjustments, and can be seamlessly integrated into current semiconductor processing technology would mark a substantial improvement in the art of semiconductor fabrication.

The disclosed spatially resolved semiconductor processing system aims to fulfill this desire by providing a mechanism that allows precise manipulation of temperature distributions on a substrate surface, thereby enabling differential control of processing rates over different areas of the substrate. This innovative approach can potentially lead to improved yield, improved throughput, better process flexibility, and enhanced device performance in the highly competitive field of semiconductor manufacturing.

This disclosure describes various embodiment systems and methods for processing substrates using optical patterns to modify/control processing rates over different regions of the substrate. Light from the optical patterns may be used to heat, and consequently modify/control processing rates in the different regions of the substrate in accordance with the optical pattern. As a result, optical patterns may be projected such that spatially resolved processing of substrates is enabled. The optical pattern may form a high-resolution temperature distribution which may be used by the processing systems of this disclosure to improve processing rate uniformity over the substrate, to remove surface roughness and film thickness non-uniformities, and to etch a pattern without photoresist and a scanner (when greater than 1 µm resolution is sufficient, such as vias and interconnects). And the optical patterns may be similarly applied to systems for etching and systems for deposition.

Embodiments provided below describe various methods, apparatuses, and systems for processing a substrate, and in particular, to methods, apparatuses, and systems that use an optical pattern to modify and control processing rates of the substrate. The following description describes the embodiments.

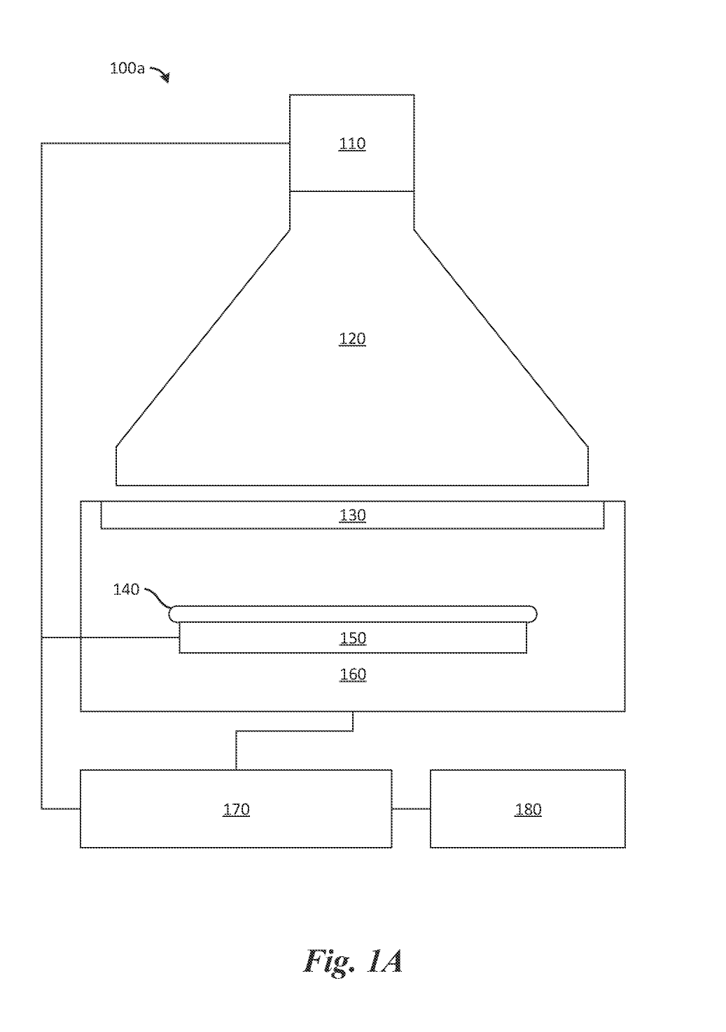

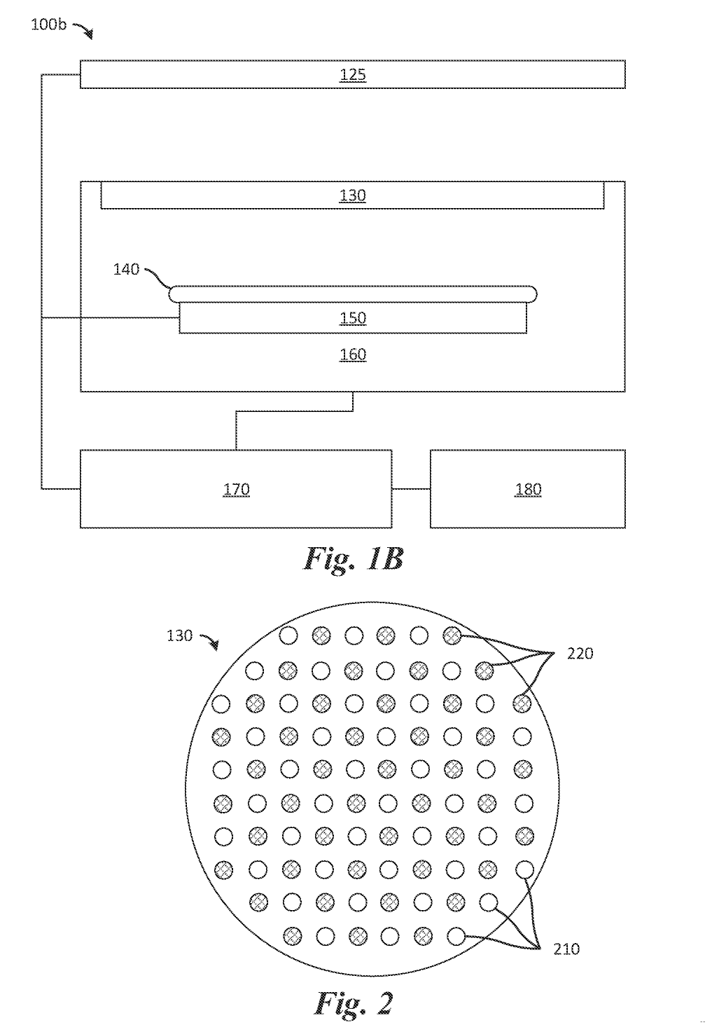

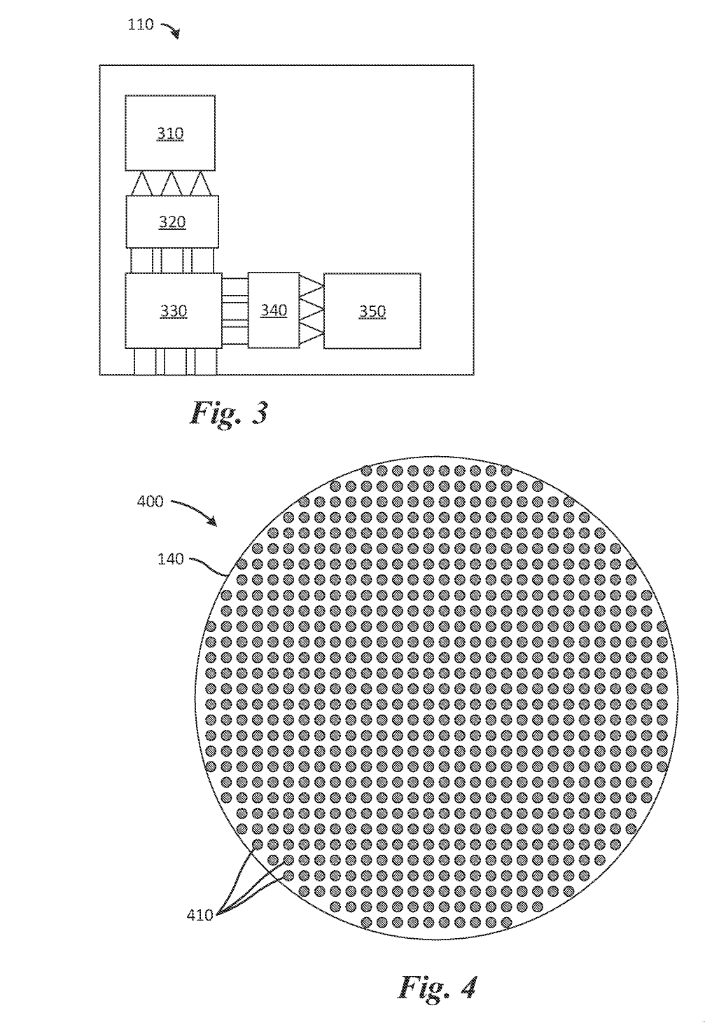

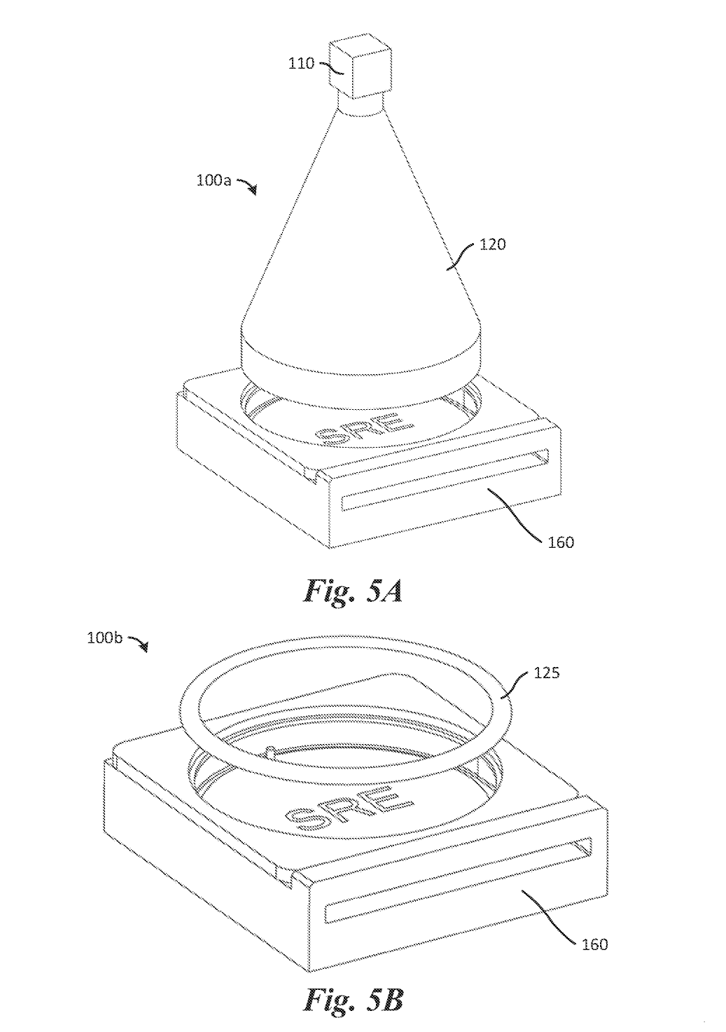

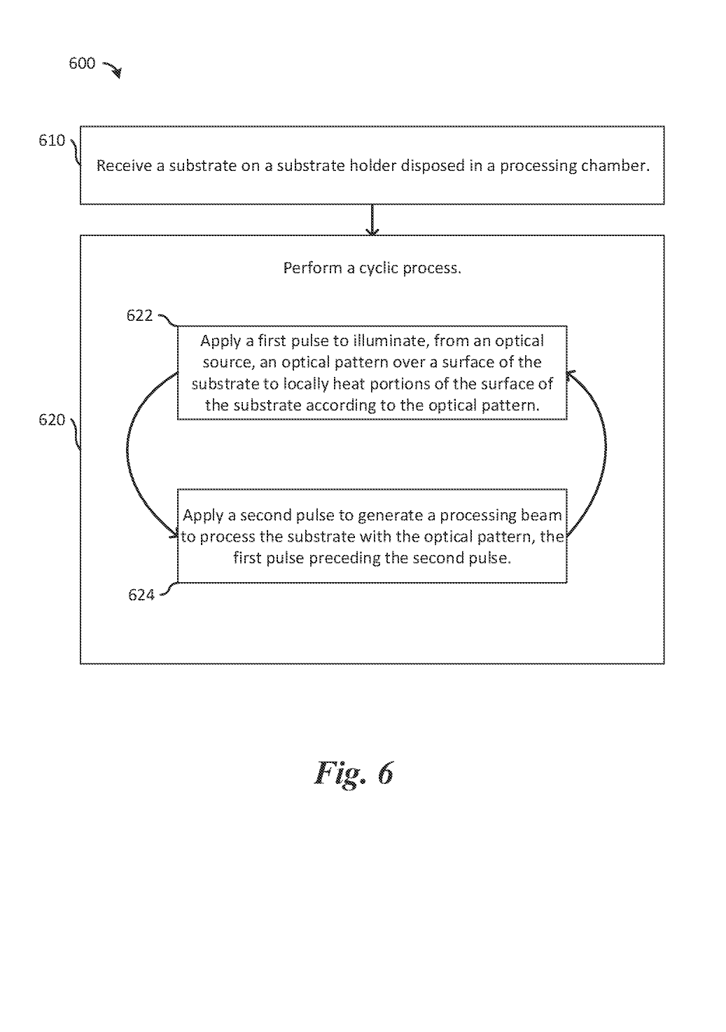

FIGS. 1A-1B are used to describe embodiment processing systems which may be used to form optical patterns over the surface of a stationary substrate to modify and control processing rates. FIG. 2 is used to describe an embodiment chamber cover which may be used in the processing systems of FIGS. 1A-1B. An example illuminator capable of producing light to form optical patterns over the surface of a substrate which may be used in the processing system of FIG. 1A is described using FIG. 3. An example optical pattern which may be formed over the surface of a substrate to modify and control processing rates is described using FIG. 4. A system diagram of the processing system of FIG. 1A is described using FIG. 5A, and a system diagram of the processing system of FIG. 1B is described using FIG. 5B. And an example processing method which may be used to process a stationary substrate disposed in a processing system for a stationary substrate, such as the processing systems described using FIGS. 1A-1B, is described using FIG. 6.

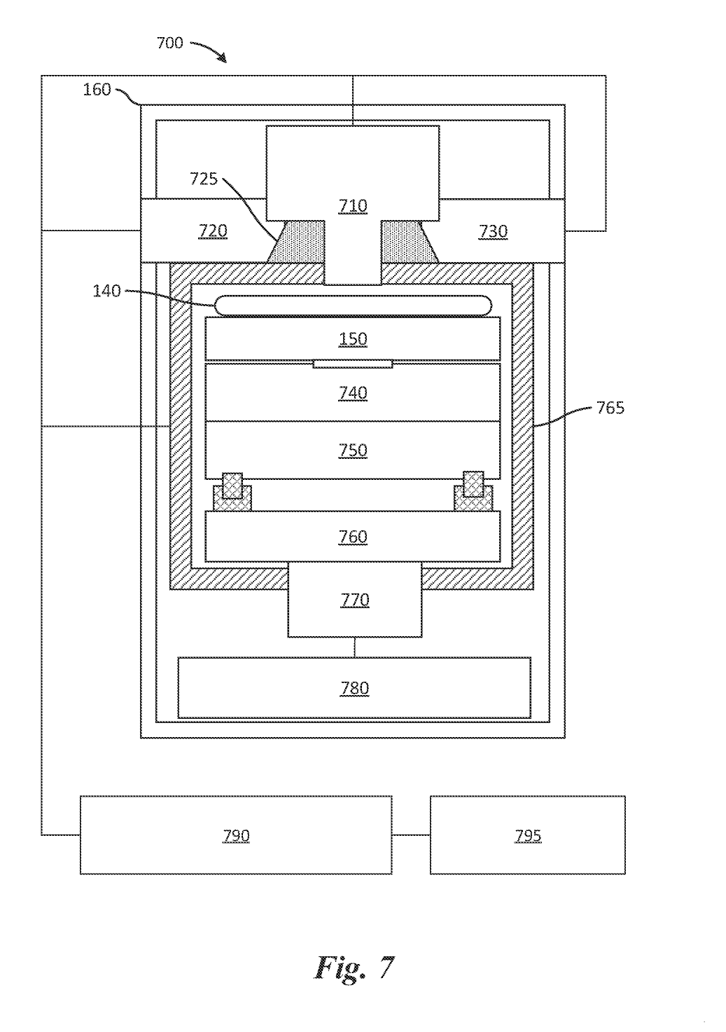

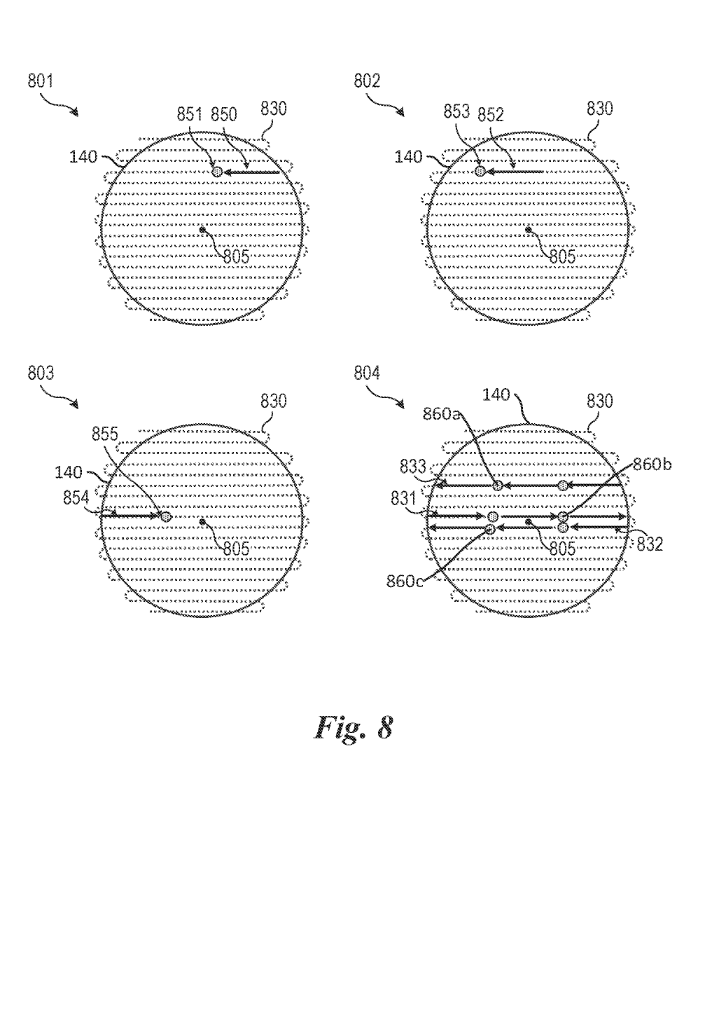

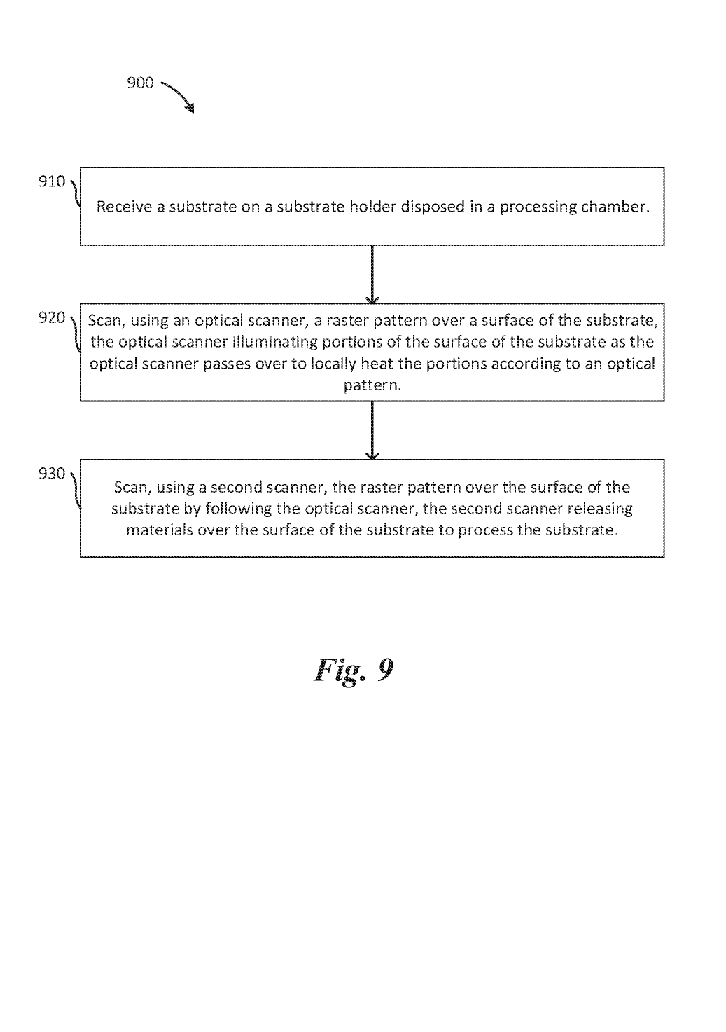

FIG. 7 is used to describe a processing system for a moving substrate capable of implementing the processing method using an optical pattern to modify and control processing rates of this disclosure. A raster pattern forming processing method for a moving substrate which may be implemented by the processing system of FIG. 7 is described using FIG. 8. And an example processing method which may be used to process a moving substrate disposed in a processing system for a moving substrate, such as the processing system described using FIG. 7, is described using FIG. 9.

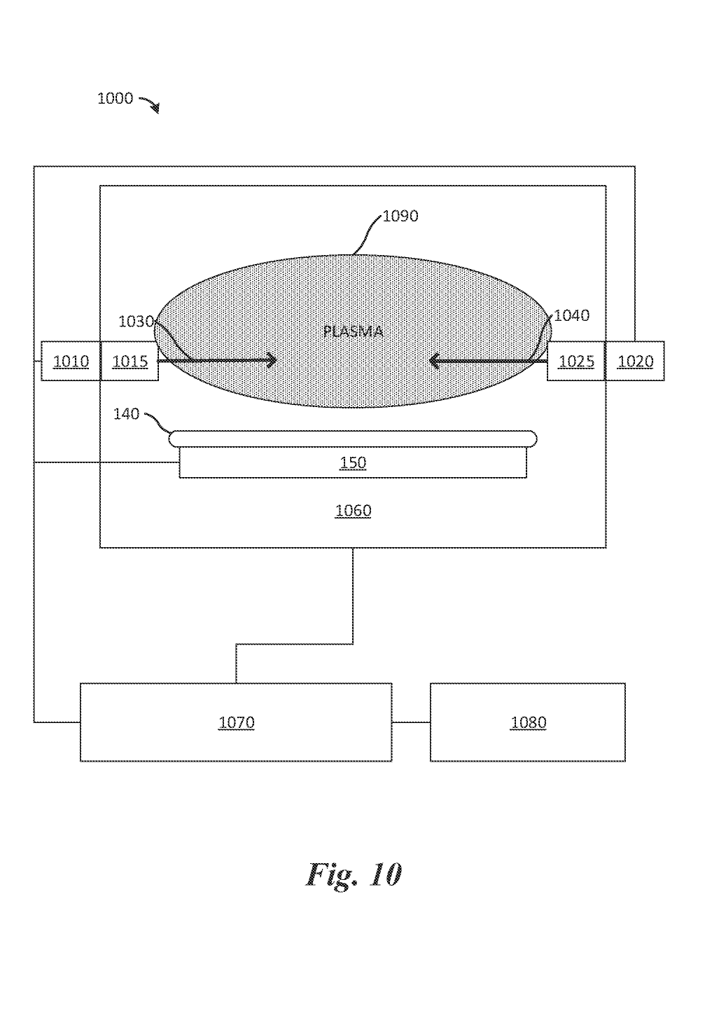

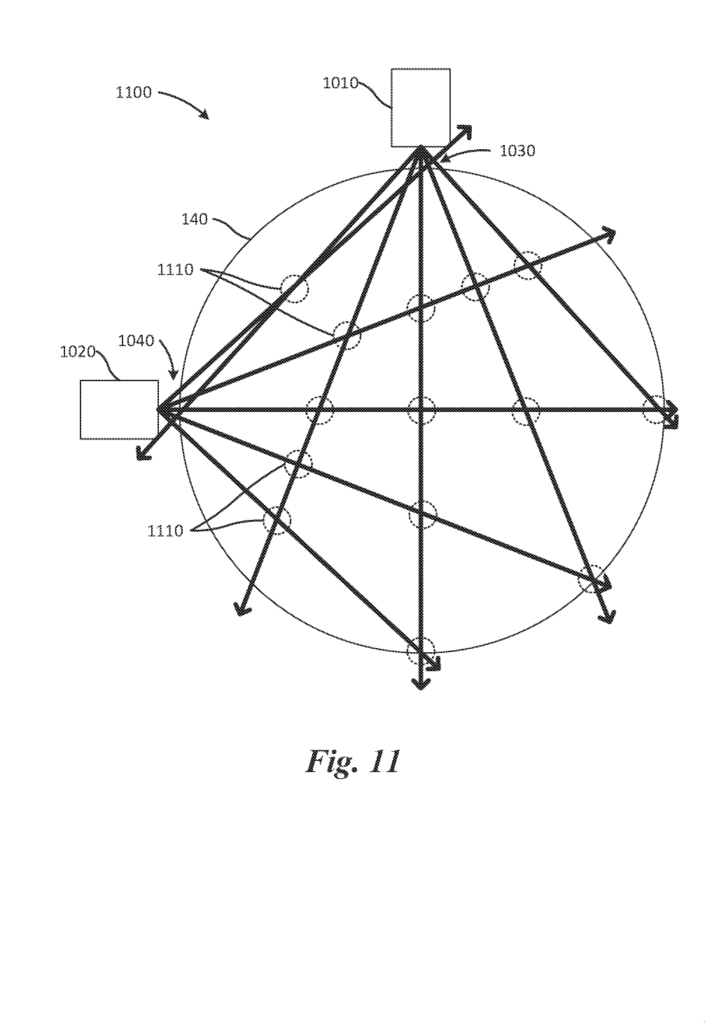

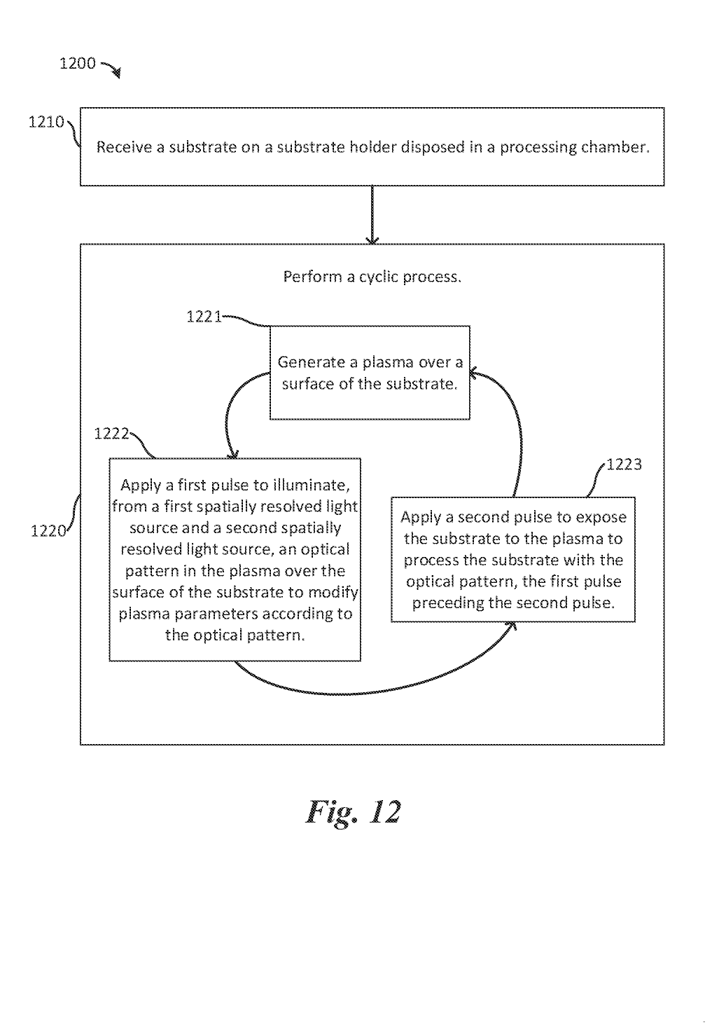

FIG. 10 is used to describe a plasma processing system capable of implementing a processing method which uses an optical pattern formed by spatially resolved light sources to modify properties of a plasma to control processing rates of a substrate. An optical pattern which may be formed using the spatially resolved light sources of the plasma processing system of FIG. 10 to modify properties of a plasma to control processing rates of a substrate is described using FIG. 11. And an example plasma processing method which may be used to process a substrate disposed in a plasma processing system, such as the plasma processing system described using FIG. 10, is described using FIG. 12.

FIGS. 1A-1B are schematic diagrams of processing systems 100a and 100b which may be used to implement a processing method for a stationary substrate in accordance with an embodiment of this disclosure. Both of the processing systems 100a and 100b comprise a light source which may be used to illuminate regions of the stationary substrate to form an optical pattern. The optical pattern heats the illuminated regions of the substrate to control/adjust processing rates. For example, in an embodiment where the processing method is for an etching process, the optical pattern heats the illuminated regions of the substrate to control/adjust etch rates of materials of the substrate. As another example, in an embodiment where the processing method is a deposition process, the optical pattern heats the illuminated regions of the substrate to control/adjust deposition rates of materials over the substrate.

FIG. 1A is a schematic diagram of a processing system 100a for a stationary substrate in accordance with an embodiment of this disclosure. The processing system 100a may be used to process a stationary substrate using a processing method for a stationary substrate of this disclosure, such as processing method 600 described using the flowchart in FIG. 6. The processing system 100a comprises an illuminator 110 optically coupled to a projection lens 120, a processing chamber 160 enclosed by a chamber cover 130, a substrate 140 disposed on a substrate holder 150 to be processed using the processing system 100a, and a controller 170 coupled to a memory 180, the substrate holder 150, the processing chamber 160, and the illuminator 110.

The substrate 140 may be any suitable substrate for which processing using the processing method for a stationary substrate of this disclosure is desired. Specifically, the substrate 140 may be any suitable substrate for which control of the processing rate via exposure to light on the surface using the methods of this disclosure may be advantageous. In various embodiments, the substrate 140 is a wafer and is a silicon wafer in one embodiment. More possible substrates include flat panel displays, photolithography masks, and others. Although the many substrates are circular, there is no requirement that the substrate 140 be circular or even substantially circular. For example, the substrate 140 may be circular, square, rectangular, or any other desired shape including irregular shapes.

In various embodiments, the processing chamber 160 may be any suitable chamber for processing the substrate 140 using the processing method of this disclosure. For example, the processing chamber 160 may be a vacuum chamber configured to etch material from the substrate 140, or a vacuum chamber configured to deposit material over the substrate 140. In embodiments where the processing chamber 160 is an etch chamber, the processing chamber 160 may be configured for either wet-etching (such as using a chemical solution) or dry-etching (such as using a gas ignited into a plasma) the substrate 140. For example, the processing chamber 160 may be a capacitively coupled plasma chamber, or an inductively coupled plasma chamber, or a reactive ion beam chamber, or etcetera. In embodiments where the processing chamber 160 is a deposition chamber, the processing chamber 160 may be configured for chemical vapor deposition (CVD), plasma-enhanced CVD (PECVD), or etcetera.

A benefit of the processing methods of this disclosure is the enablement for spatially controlled processing without using a scanning apparatus. The various processing rates for regions of the substrate 140 surface may be controlled through the heating resulting from the light exposure in the optical pattern. Regions receiving more light may be heated more than regions receiving less light, and have different processing rates between the regions as a result.

In various embodiments, the chamber cover 130 may be transparent to some wavelengths of light to enable the illumination of the substrate 140 by the illuminator 110 through the projection lens 120. Various embodiments of the chamber cover 130 may be suitable for processing the substrate 140 in the processing system 100a. For example, the chamber cover 130 may be a silicon gas shower head with holes intermixed with transparent areas to allow short-wave infrared (SWIR) light to pass unimpeded from the projection lens 120 into the processing chamber 160 for embodiments using a gas ignited into a plasma to process the substrate 140 and using a normal incidence configuration for the illuminator 110 through the projection lens 120. Other embodiments may be configured for oblique illumination, and in such embodiments, no modification of the chamber cover 130 may be made (such as adding the transparent elements). In other embodiments, the illumination and heating light may be delivered through the substrate holder 150 and through the back of the wafer.

The transparent elements of the chamber cover 130 may be any suitable material for allowing light to propagate through to the processing chamber 160. For example, the transparent material may allow light comprising a spectrum of wavelengths in the visible, near-infrared, or short-wave infrared (SWIR) to pass into the processing chamber 160 to illuminate an optical pattern on the substrate 140 to heat and modify processing parameters. An example embodiment of the chamber cover 130 is described further using FIG. 2 below. In other embodiments, the source of light may be placed inside the processing chamber 160 to enable the use of extreme ultraviolet (EUV), X-ray, and electromagnetic radiation of other wavelengths incapable of penetrating conventional processing chambers. In those embodiments, an additional in-chamber reflective projection optical subsystem or a beam-steering mechanism may be used. Further, the use of a light source within the processing chamber 160 may enable further improved pattern resolutions (such as below 1 µm).

Still referring to FIG. 1A, the substrate holder 150 may be any suitable device known in the art for holding a substrate during processing. In various embodiments, the substrate holder 150 is an electrostatic chuck that clamps the substrate 140 in place during processing using an electrostatic force. For example, in embodiments where the processing chamber 160 is a vacuum chamber configured for processing the substrate 140 with a plasma, electrostatic chucks may be used for the substrate holder 150. In other embodiments, the substrate holder 150 may be a vacuum chuck, a mechanical clamp, a magnetic chuck, or etcetera.

The illuminator 110 may be any device suitable for emitting light through the projection lens 120 to form an optical pattern over the surface of the substrate 140. In various embodiments, the illuminator 110 may be capable of collecting reflected beams from the surface of the substrate 140 which may be used for monitoring the processing of the substrate, or for end-point detection (EPD). The illuminator 110 is described further using FIG. 3 below. The projection lens 120 may be any suitable optical lens or plurality of lenses for projecting the optical pattern onto the substrate 140. For example, the projection lens 120 may comprise a plurality of lenses that collimate light from the illuminator 110 in order to project the optical pattern onto the surface of the substrate 140 through the chamber cover 130 with a high-resolution for forming a high-resolution temperature gradient over the surface of the substrate 140.

Still referring to FIG. 1A, the memory 180 may be any suitable memory device for storing instructions for performing the processing method of this disclosure to be executed by the controller 170. Further, the memory 180 may be any suitable device capable of storing measurements made by the processing system 100a (such as an EPD by a light sensing element of the illuminator 110). For example, the memory 180 may be a solid state drive (SSD), a hard disk drive (HDD), or some form of volatile memory device such as dynamic random access memory (DRAM).

The controller 170 may be any suitable device capable of executing the processing method of this disclosure. By controlling the illuminator 110 to emit light through the projection lens 120 to project the optical pattern over the surface of the substrate 140, and by controlling the processing chamber 160 and the substrate holder 150 to hold the substrate 140 and process the substrate 140 using a processing tool of the processing chamber 160, the controller 170 may implement the processing method of this disclosure to process a substrate 140 using an optical source to heat and modify/control processing parameters. In various embodiments, the controller 170 may be an application specific integrated circuit (ASIC), a field programmable gate array (FPGA), a microcontroller (MCU), or some form of programmable logic circuit (PLC). The controller 170 is capable of implementing the processing method for a stationary substrate of this disclosure, such as the method 600 described using the flowchart of FIG. 6.

The processing system 100a may be used to project an optical pattern over the surface of the substrate 140 for a short timeframe to heat and modify/control the processing rate of the substrate 140 in different regions. For example, the optical pattern may cause different regions of the surface of the substrate 140 to heat to different temperatures than other regions of the surface of the substrate 140. As a result, the higher temperature regions may be processed at a different processing rate than lower temperature regions. This ability enables the processing system 100a to spatially control the processing of a stationary substrate (process different regions of the substrate at different processing rates) while processing the entire surface of the substrate 140. As a result, processing times may be reduced because location specific processing may be enabled in a single processing step and without using a scanner (which use multiple processing steps).

The optical pattern projected onto the surface of the substrate 140 may be a variety of different light intensities for different regions of the substrate 140, and where the optical pattern may be a heat distribution map optimized to advantageously process different regions of the surface of the substrate 140 at different processing rates. For example, the optical pattern may be a film thickness map predetermined for the substrate 140, and the heating from the optical pattern comprising the film thickness map may cause regions of the surface of the substrate with higher elevation to be processed faster than regions with lower elevation. As a result, the substrate 140 may be planarized using the spatial processing ability of the processing system 100a.

The processing system 100a may also pause briefly after pulsing the optical pattern over the surface and then pulsing the processing tool to process the substrate 140 in order to allow the heat distribution to dissipate over the surface and throughout the substrate 140 to reach thermal equilibrium before resuming the processing method. And the process of pulsing the illuminator 110, followed by pulsing the processing tool, and then waiting for thermal equilibrium may be repeated as many times as may be desired for the specified amount of material deposition/removal form the surface of the substrate 140.

Other embodiment systems, rather than using the illuminator 110 and the projection lens 120 to form the optical pattern over the surface of the substrate 140, may use a ring illuminator to illuminate an optical pattern on the surface of the substrate 140. Further, ring illuminator embodiments may be simpler to implement and at the same time advantageous for some applications, such as correcting radial non-uniformities near edges of a circular wafer. An embodiment processing system capable of implementing the processing method for stationary substrates of this disclosure using a ring illuminator is described using FIG. 1B.

FIG. 1B is a schematic diagram of a processing system 100b for a stationary substrate in accordance with an embodiment of this disclosure. The processing system 100b may be used to process a stationary substrate using a processing method for a stationary substrate of this disclosure, such as processing method 600 described using the flowchart in FIG. 6. The difference between the processing system 100b of FIG. 1B and the processing system 100a of FIG. 1A is the processing system 100b comprises a ring illuminator 125, and does not use the illuminator 110 and projection lens 120.

The processing system 100b comprises the ring illuminator 125, the processing chamber 160 enclosed by the chamber cover 130, the substrate 140 disposed on the substrate holder 150 to be processed using the processing system 100b, the controller 170, and the memory 180. In contrast to the processing system 100a of FIG. 1A, the controller 170 of the processing system 100b of FIG. 1B may be coupled to the memory 180, the substrate holder 150, the processing chamber 160, and the ring illuminator 125. Similarly labeled elements may be as previously described.

In various embodiments, the ring illuminator 125 comprises a flash gas-discharge lamp of ring shape to generate repetitive pulses of light with uniform illumination in an azimuthal direction, and controlled distribution of intensity on a sample (such as the substrate 140) in a radial direction. The distribution of intensity may be controlled by using appropriately positioned reflective, diffusive, or absorbing optical elements. The gas discharge, for example in a xenon lamp, may use laser-driven, electric arc, or other suitable pulsed discharge mechanisms. In other embodiments, the discharge (and illumination) may be continuous. And in other embodiments, the ring illuminator 125 comprises a plurality of light sources arranged in a circular pattern, and the plurality of light sources may be configured to illuminate the entire surface of the substrate 140. In other embodiments, the plurality of light sources may be arranged in a suitable pattern for forming an optical pattern on the surface of the substrate 140, such as arranging the plurality of light sources in a rectangular, or ovular arrangement. The plurality of light sources may be any light source known in the art suitable for emitting light at wavelengths desired for illuminating (and heating) the surface of the substrate 140 to modify processing rates, such as a plurality of light-emitting diodes (LEDs).

In contrast to the processing system 100a of FIG. 1A, the ring illuminator 125 may illuminate the entire surface of the substrate 140 without using the projection lens 120, which may heat the entire surface to modify processing rates during processing. A benefit of the processing system 100b of FIG. 1B is that the ring illuminator 125 may be used to illuminate the outer edges of the substrate 140 to control/modify the processing rates at the edges of the substrate 140. As a result, edge effects from conventional processing methods may be prevented by processing substrates in the processing system 100b using the processing methods of this disclosure. And another benefit of the ring illuminator 125 of the processing system 100b of FIG. 1B, is the embodiment processing system 100b has the least amount of changes to conventional processing chambers to enable the processing methods of this disclosure. In other words, the embodiment processing system 100b is the most cost effective embodiment.

The ring illuminator 125 may be configured to emit light through the chamber cover 130 to illuminate the surface of the substrate 140 and form an optical pattern, such as exposing the entire surface to light. An example embodiment of the chamber cover 130 which may be used in the processing systems 100a-100b of FIGS. 1A-1B is described using FIG. 2.

FIG. 2 illustrates a top view of the chamber cover 130 of the processing chamber 160 in accordance with an embodiment of this disclosure. In various embodiments, the chamber cover 130 may comprise a gas shower head with multiple channels to deliver processing chemicals, such as gas, via small holes 210 intermixed with light-transparent areas 220. For example, the light-transparent areas 220 may enable illumination light from the projection lens 120 of FIG. 1A or the ring illuminator 125 of FIG. 1B to pass through and illuminate the surface of the substrate 140.

The light-transparent areas 220 may comprise any material suitable for enabling the illumination light from the projection lens 120 of processing system 100a or the ring illuminator 125 of processing system 100b to pass through unimpeded. For example, the light-transparent areas 220 may be crystalline silicon (c-Si), SiO₂, quartz, Al₂O₃ (sapphire), pyrex, MgF₂, CaF₂, AlON, or some other form of polymer material, or any other suitable material known in the art. Specifically, the light-transparent areas 220 may be any material that enables SWIR light wavelengths to pass through unimpeded.

In various embodiments, the chamber cover 130 comprises a uniform material optically transparent to the wavelengths of the light source, and the light-transparent areas 220 are more holes that enable processing gases to enter the processing chamber 160. Further, in other embodiments, the chamber cover 130 is a conventional chamber cover comprising embedded gas channels/nozzles that still allows the illumination light to penetrate and form a uniform pattern on the substrate 140. In alternative embodiments, the chamber cover 130 of the processing chamber 160 may comprise a gas shower head disposed above the substrate 140 with only the small holes 210. In contrast to the normal incidence illumination configuration illustrated for the processing systems 100a-100b of FIGS. 1A-1B, optically transparent windows may be disposed around the outer surface of the processing chamber 160 to enable an oblique illumination configuration.

In some embodiments, the chamber cover 130 may be a window completely made of optically transparent materials that allow the wavelengths of light emitted by the projection lens 120 of processing system 100a or the ring illuminator 125 of processing system 100b to pass through unimpeded, such as crystalline silicon (c-Si), SiO₂, quartz, Al₂O₃ (sapphire), pyrex, MgF₂, CaF₂, AlON, or some other form of polymer material, or any other suitable material known in the art. Further, the chamber cover 130 may be made of materials that enable SWIR wavelengths to pass through unimpeded. And in other embodiments, the processing chamber 160 may be configured to process the substrate 140 without chamber cover 130. An embodiment of the illuminator 110 which may be used to produce the light that passes through the projection lens 120 and then through the chamber cover 130 to form an optical pattern on the substrate 140 is described using FIG. 3. In other embodiments, the illuminator 110 may be disposed below the substrate holder 150 and used to illuminate regions of interest by passing light through the substrate holder 150 and through portions of a bottom surface of the substrate 140.

FIG. 3 is a schematic diagram of the illuminator 110 of FIG. 1A in accordance with an embodiment of this disclosure. The illuminator 110 comprises a light source 310, an condenser lens 320, a beam splitter 330, lens 340, and a detector 350. The illuminator 110 may be used to generate light used to project an optical pattern onto the surface of the substrate 140 to modify the processing rate over illuminated regions according to the optical pattern. Further, the illuminator 110 may change the optical patterns over time as the substrate 140 is processed. The ability for the processing system 100a to modify or change the optical pattern in real-time during the processing of the substrate 140 is another benefit of this disclosure.

The light source 310 may be any device known in the art suitable for generating the light used to project the optical pattern onto the surface of the substrate 140 to modify processing rates of materials of the substrate 140 during processing. For example, the light source 310 may be a pulsed or continuous (CW) laser, a flash or continuous gas-discharge lamp, light emitting diode (LED), a broadband light source, or etcetera. In various embodiments, the light source 310 may be capable of producing a spectrum of wavelengths of light (λ) between about 400 nm and about 2000 nm (400 nm ≤ λ ≤ 2000 nm) to compromise between optical resolution and chamber material transmissive properties.

The light source 310 may be pulsed, or made to emit light over brief timeframes, and then immediately followed by processing of the substrate 140 to avoid the heat from the illumination redistributing through the substrate 140 before being processed and consequently reducing the resolution of the heat map. For example, the light source 310 may emit at frequencies (f) between about 100 Hz to about 10 kHz (100 Hz ≤ f ≤ 10 kHz). And after processing, a waiting period may be implemented to allow the heat to redistribute through the entire substrate 140 to reach thermal equilibrium before the light source 310 is pulsed again.

In various embodiments, the light source 310 may be advantageously selected for the optimal heating depending on the type of material of the substrate 140. For example, in an embodiment where the substrate 140 is a silicon substrate, infrared wavelengths may be avoided because silicon substrates allow infrared wavelengths to pass through without capturing enough light to effectively heat the substrate. Various embodiments may use light in the visible spectrum, the ultraviolet spectrum, or the infrared spectrum of wavelengths to illuminate and heat the surface of the substrate 140. Embodiments using visible light have the additional benefit of the visible light only being absorbed or reflected from the surface of the substrate 140.

The condenser lens 320 may be a single lens or a plurality of lenses suitable for collimating and relaying the light generated by the light source 310 to the other elements of the illuminator 110. For example, the condenser lens 320 may be used to collimate and subsequently route the light from the light source 310 to the beam splitter 330. In various embodiments, the condenser lens 320 may be refractive, reflective, or catadioptric and comprise reflective mirror surfaces, plano-convex lenses, achromatic doublets, Fresnel lenses, telecentric lenses, and/or etcetera.

The beam splitter 330 may be any device known in the art suitable for splitting the light generated from the light source 310 to send a portion through the lens 340 into detector 350 and the remaining portion out to the projection lens 120. In various embodiments, the beam splitter 330 may be glass, fused silica, optical crystals such as CaF₂ or MgF₂, plastics, or etcetera. The beam splitter 330 may also be used to route the reflected light from the surface of the substrate 140 back to the detector 350. The beam splitter 330 may be a plate beam splitter, a cube beam splitter, a polarizing beam splitter, or a dielectric beam splitter.

In various embodiments, the lens 340 may be any suitable device for delivering collected light into the detector 350. For example, the lens 340 may be a focusing lens for a single point detector, or an imaging lens for a multi-pixel imaging sensor capability.

The detector 350 may be any device known in the art suitable for collecting wavelengths of reflected light from the surface of the substrate 140 during processing. For example, the detector 350 may be photodiodes, a photomultiplier tube (PMT), charge-coupled devices (CCDs), complementary metal-oxide-semiconductor (CMOS) sensors, phototransistors, time-of-flight (ToF) sensors, or etcetera. Further, the detector 350 may be a single point or a multi-pixel imaging sensor.

While processing the substrate 140, the detector 350 may be used to collect light reflected from the surface of the substrate 140 to determine a variety of processing parameters, such as determining film thickness during the processing of the substrate 140. Further, the detector 350 may be used for end-point determination (EPD) based on the reflected light form the surface of the substrate 140. The detector 350 may also be used for analysis of incident parameters of the light generated by the light source 310. For example, the beam splitter 330 may split the incident light and send a portion to the detector 350 for monitoring of the incident parameters of the light. In some embodiments, illumination or collection filters may also be used to achieve hyperspectral imaging capability for the detector 350.

The ring illuminator 125 of FIG. 1B may comprise similar elements as illustrated and described in FIG. 3 for the illuminator 110 of FIG. 1A. The illuminator 110 illustrated in FIG. 3 may be used to emit light through the projection lens 120 and illuminate an optical pattern over the surface of the substrate 140 to heat and modify processing rates. And the ring illuminator 125 of FIG. 1B may be used to emit light and illuminate an optical pattern over the surface of the substrate 140 to heat and modify processing rates. An example optical pattern is described using FIG. 4.

FIG. 4 illustrates an optical pattern 400 which may be projected on the substrate 140 by the illuminator 110 of the processing system 100a of FIG. 1A in accordance with an embodiment of this disclosure. Illuminated regions 410 are projected over the substrate 140 to form the optical pattern 400. Areas of the substrate 140 in the illuminated regions 410 of the optical pattern 400 may be heated from the exposure to light and, as a result, the processing rates of the substrate 140 may be controlled. For example, in an embodiment where the substrate 140 is being etched, the optical pattern 400 may adjust an etch rate by heating the substrate 140 with the light in the illuminated regions 410. In another embodiment where a deposition process is depositing layers over the substrate 140, the optical pattern 400 may adjust a deposition rate of materials by heating the substrate 140 with the light in the illuminated regions 410.

The optical pattern 400 is only an example. Various other embodiments may form optical patterns according to scans of the substrate 140 which may determine regions of the surface of the substrate that may benefit from a modification of the etch rate or deposition rate. For example, regions of the substrate 140 more elevated than other regions may be exposed to the optical pattern to increase the etch rate and improve the planarity of the surface of the substrate 140. As another example, regions of the substrate 140 with a lower elevation may be exposed to the optical pattern to increase the deposition rate and improve planarity of the surface of the substrate 140. The optical pattern 400, in various embodiments, may be uniquely configured to the substrate 140 being processed.

FIGS. 5A-5B illustrate side views of the processing systems 100a-100b described using FIGS. 1A-1B. FIG. 5A is a side view of the processing system 100a of FIG. 1A and FIG. 5B is a side view of the processing system 100b of FIG. 1B.

FIG. 5A is a side view of the processing system 100a of FIG. 1A in accordance with an embodiment of this disclosure. Similarly labeled elements may be as previously described. The conical shape of the projection lens 120 is more clearly illustrated in FIG. 5A. Other embodiments may comprise projections lens 120 of different shapes.

FIG. 5B is a side view of the processing system 100b of FIG. 1B in accordance with an embodiment of this disclosure. Similarly labeled elements may be as previously described. The circular ring-shape of the ring illuminator 125 is more clearly illustrated in FIG. 5B. As mentioned above, other embodiments may comprise ring illuminators 125 of different shapes. A processing method for processing a stationary substrate using light to project an optical pattern to heat and modify processing rates which may be implemented in either of the processing systems 100a-100b of FIGS. 1A-1B is described using FIG. 6.

FIGS. 6 illustrates an example method of processing a stationary substrate using a light source to illuminate an optical pattern onto the surface of the substrate to modify/control processing rates in accordance with embodiments of this disclosure. The method of FIG. 6 may be combined with other methods and performed using the systems and apparatuses as described herein, such as the processing systems 100a-100b illustrated in FIGS. 1A-1B. Although shown in a logical order, the arrangement and numbering of the steps of FIG. 6 are not intended to be limited. The method steps of FIG. 6 may be performed in any suitable order.

Referring to FIG. 6, step 610 of a method 600 of processing a stationary substrate using an optical pattern to modify/control processing rates receives a substrate on a substrate holder disposed in a processing chamber. The substrate disposed on the substrate holder remains stationary during the processing using the method 600 of FIG. 6. The substrate, the substrate holder, and the processing chamber may be the substrate 140, the substrate holder 150, and the processing chamber 160 of either processing systems 100a-100b of FIGS. 1A-1B. And after receiving the substrate on the substrate holder, the method 600 proceeds to step 620. Step 620 performs a cyclic process to process the substrate. The cyclic process of step 620 comprises step 622, and step 624.

Still referring to FIG. 6, step 620 of the method 600 (the cyclic process) may start by applying a first pulse to illuminate, from an optical source, an optical pattern over a surface of the substrate in step 622. The optical pattern locally heats potions of the surface of the substrate according to the optical pattern. For example, the portions of the surface of the substrate exposed to the optical pattern are heated due to the absorption of light from the optical source in those portions. In various embodiments, the optical source may be the illuminator 110 of FIG. 1A, or the ring illuminator 125 of FIG. 1B.

As a result of the heating in step 622, the portions of the surface of the substrate exposed to light from the optical pattern have altered processing rates. For example, regions heated may have improved etch rates or deposition rates during processing in comparison to regions not exposed to light. In other words, the portions exposed to more light will be processed at a different rate than regions exposed to less light, and as a result, processing over the entire surface will process different regions at different rates. The optical pattern projected over the surface of the substrate may comprise a heat map determined from a film thickness map measured for the substrate before starting the method 600. As an example, regions of the surface of the substrate determined to have peaks may be illuminated to heat those regions such that when those regions are processed, material is removed at a higher etch rate in order to form a more uniform (or planarized) surface.

After illuminating in step 622, the cyclic process of step 620 of the method 600 proceeds to step 624. Step 624 of the method 600 applies a second pulse to generate a processing beam to process the substrate with the optical pattern. Further, the first pulse precedes the second pulse. In some embodiments, the first pulse starts and stops with a time delay before the start of the second pulse. In various embodiments, the start of the second pulse may be within a period of the first pulse (while the optical pattern is still being emitted over the surface of the substrate). A time delay between the start of the first pulse and the start of the second pulse may be optimized according to the processing recipe, or in accordance with a desired processing amount of the surface of the substrate. For example, the time delay may be determined based on a topographical map of the surface of the substrate.

Step 624 of the cyclic process 620 of the method 600 may uniformly expose the entire surface of the substrate to the processing beam to process the substrate, and as a result of the heating, process different regions at different processing rates according to the optical pattern. Both steps 622 and step 624 may be performed for a preconfigured timeframe, and different embodiments may have a same timeframe for both, or different timeframes for the first pulse and the second pulse. After step 624, a single cycle of the cyclic process of step 620 of the method 600 has been completed. Various embodiments may use multiple cycles of the cyclic process in order to completely process the substrate in accordance with a processing recipe. And various embodiments may wait a brief period of time after completing each cycle of the cyclic process to allow the surface of the substrate to reach thermal equilibrium before resuming the processing.

The method 600 of processing the stationary substrate may comprise various different fabrication methods. In various embodiments, the processing beam may comprise a neutral flux, an ion flux, a gas cluster flux, or a plasma flux. For example, in some embodiments, the processing performed by the method 600 may be an etching process for fabricating features in the substrate, such as channels, contact holes, vias, or etcetera. In those embodiments, the modified processing rates according to the optical pattern may heat the regions of the surface such that a faster etch rate is achieved in those regions. In other embodiments, the processing performed by the method 600 may be a deposition process for depositing materials over the surface of the substrate. In those embodiments, the modified processing rates according to the optical pattern may heat the regions of the surface such that a faster deposition rate is achieved in those regions.

Benefits of the method 600 include improved processing rate uniformity over the substrate, reduced surface roughness and film thickness non-uniformities, and the ability to perform localized annealing within the processing systems. The method 600 may also beneficially be capable of etching patterns on a substrate without using a photolithographic process (when greater than about 1 µm spatial resolution is sufficient, such as forming metal contacts and signal layers).

In contrast to the embodiment processing systems 100a-100b of FIGS. 1A-1B which may be used to process a stationary substrate, other embodiment systems may be used to process a moving substrate using the processing method of this disclosure. For example, embodiment systems using a scanner to move a substrate during processing may be modified to include an optical scanning system which may expose regions of the substrate to light to modify/control processing rates in the exposed regions, such as described using FIG. 7.

FIG. 7 is a schematic diagram of a processing system 700 for a moving substrate in accordance with an embodiment of this disclosure. The processing system 700 uses a scanning system to scan a raster pattern over the surface of the substrate 140 for processing. The processing system 700 may use an optical scanner to expose different regions of the surface of the substrate to an optical pattern to heat and modify/control processing rates according to the optical pattern.

In the embodiment illustrated in FIG. 7, the processing system 700 comprises the processing chamber 160, and a processing and control module 790 electrically coupled to a memory 795. The processing chamber 160 comprises a processing tool 710, an illumination system 720 optically coupled to a chamber window 725, a collection system 730 optically coupled to the chamber window 725, a scanner 765 coupled via a vacuum-to-atmosphere electrical pass-through 770 to a stage controller 780. The scanner 765 comprises the substrate 140 disposed on the substrate holder 150, a TZ stage 740 coupled to the substrate holder 150 and disposed on a linear stage 750, and a motion base 760 coupled to the linear stage 750. Similarly labeled elements may be as previously described.

The processing tool 710 may be any device known in the art capable of emitting a localized beam over an area of the surface of the substrate 140. For example, the processing tool 710 may be a partial plasma etch (PPE) tool configured to emit a plasma beam over a localized area of the substrate for processing. In some embodiments, the processing tool 710 may be configured to scan over the surface of the substrate 140 while the substrate 140 remains stationary. In the embodiment illustrated in FIG. 7, the processing tool 710 is stationary over a localized area of the substrate 140, and the substrate 140 moves via the scanner 765, which may be configured to scan a raster pattern (such as illustrated using FIG. 8) over the surface of the substrate 140 to expose the entire surface to the beam produced by the processing tool 710.

The optical scanner of the processing system 700 comprises the illumination system 720, the chamber window 725, and the collection system 730. The optical scanner may be capable of generating, emitting, and collecting a light beam to illuminate a localized area over the surface of the substrate to heat and modify/control processing rates using the processing tool 710. In some embodiments, the optical scanner may be capable of scanning over the surface of the substrate 140. In the embodiment illustrated in FIG. 7, the optical scanner is configured to illuminate the same localized area as would be exposed to the beam generated by the processing tool 710 to process the substrate 140. Further, the optical scanner in FIG. 7 is configured for oblique illumination, which emits an incident light beam from the illumination system 720 at an angle offset from a normal direction of the surface of the substrate 140, and a reflected light beam reflects from the surface at the same oblique angle and may be collected by the collection system 730. Other embodiments may be configured for normal incidence illumination.

The illumination system 720 comprises elements for generating, focusing, and directing an incident light beam onto a localized area over the surface of the substrate 140. For example, the illumination system 720 may comprise similar elements as described for the illuminator 110 in FIG. 3, such as a light source. The light source of the illumination system 720 may be a laser, or other suitable light source for generating a light beam comprising wavelengths advantageous for heating materials exposed in the localized area of the surface of the substrate 140. The incident beam generated by the illumination system 720 may be emitted onto the surface of the substrate 140 after passing through the chamber window 725. And the chamber window 725 may be any material suitable for allowing the incident light beam to pass through without impeding the incident light beam, such as crystalline silicon (c-Si), SiO₂, quartz, glass, Al₂O₃ (sapphire), or etcetera. Further, the chamber window 725 may be any material that enables SWIR light wavelengths to pass through unimpeded.

In various embodiments, the collection system 730 may be used to collect the reflected light beam from the surface of the substrate 140. The collection system 730 comprises a light sensor which may be used for various analyses of the reflected light beam. The various analyses which may be performed using the light sensor may be end point detection for the processing, or thermal measurements of the localized area illuminated to determine when the localized area has been exposed long enough to reach a desired processing temperature. For example, in various embodiments, the collection system 730 may collect the reflected light beam and analyze the reflected light beam throughout the processing method for end point detection or a temperature measurement.

In other embodiments, the optical scanner may be configured to emit and receive the oblique illumination light through the processing tool 710. Those embodiments may not use the chamber window 725.

In various embodiments, the processing system 700 may illuminate a localized area of the surface of the substrate using the illumination system 720 and collect reflected light beams using the collection system 730. After determining the localized area being illuminated has been illuminated for an illumination time to reach a desired processing temperature, the processing tool 710 may then process the same localized area of the surface of the substrate 140 until a desired processing time has elapsed, or an end point determination is made by the collection system 730. After, the processing system 700 may use the scanner 765 to move a new localized area of the surface of the substrate 140 beneath the processing tool 710 and optical scanner for processing. The various localized areas illuminated by the illumination system 720 may form various optical patterns according to a processing recipe for the substrate 140, such as the optical pattern 400 illustrated and described using FIG. 4.

The ability to modify processing rates over exposed areas of the surface of the substrate 140 using the optical scanner may beneficially reduce the complexity of the scanning performed by the scanner 765. For example, the adjusted processing rates may eliminate the rapid acceleration and rapid movements of the scanner 765 in conventional systems, which rapidly accelerates and rapidly moves the substrate 140 to ensure uniform processing over the surface. Instead, the processing system 700 may enable uniform processing over the surface of the substrate 140 by spatially controlling the processing rates using the optical patterns from the optical scanner.

As described above, the scanner 765 comprises the substrate 140 disposed on the substrate holder 150, the TZ stage 740 coupled to the substrate holder 150 and disposed on the linear stage 750, and the motion base 760 coupled to the linear stage 750. The scanner 765 may be configured to move the substrate 140 beneath the processing tool 710 to process specific areas of the surface of the substrate 140. In other embodiments, a raster pattern may be traced using the scanner 765 to move the substrate 140 beneath the processing tool 710 to expose the entire surface of the substrate 140 to the processing beam from the processing tool 710. The processing system 700 of FIG. 7 uses the scanner 765 to move the substrate 140 beneath the processing tool 710, and uses an illuminated region from the optical scanner to heat and modify/control processing rates of the substrate 140.

The stages may be configured to perform movements of the substrate 140 in X, Y, and Z linear directions, as well as perform rotations about a rotation direction, T. Specifically, the TZ stage 740 may be configured to perform vertical and rotational movements, such as moving the substrate 140 up or down in the Z direction (or toward and away from the processing tool 710), and the linear stage 750 may be configured to perform translational movements within the XY plane. Various conventional stages may be used for either the TZ stage 740 or the linear stage 750 where the stage controller 780 may control drivers of the stages to perform the scanning.

The motion base 760 may be a mechanically stabilized platform to enable precise movement of the substrate 140 using the scanner 765. The motion base 760 may be any conventional device known in the art capable of minimizing vibrations of the substrate 140 and providing a stable foundation. And the motion base 760 may couple to the vacuum-to-atmosphere electrical pass-through 770, which may be used to electrically couple the scanner 765 with the processing chamber 160 and the stage controller 780.

The stage controller 780 may control drivers of the TZ stage 740 and the linear stage 750 to perform the scanning and focusing operations. Further, the stage controller 780 may be any suitable device known in the art, such as the devices listed for the controller 170 of FIGS. 1A-1B.

Still referring to FIG. 7, the processing and control module 790 may be used to control the processing system 700 for the implementation of the processing method for a moving substrate of this disclosure, such as the method 900 described using the flowchart in FIG. 9. In the embodiment illustrated in the processing system 700 of FIG. 7, the processing and control module 790 is electrically coupled to the memory 795, the scanner 765, the illumination system 720, the collection system 730, and the processing tool 710. The processing and control module 790 may be any suitable device known in the art, such as the devices listed for the controller 170 of FIGS. 1A-1B.

And the memory 795 may store the instructions for the processing method for a moving substrate of this disclosure which may be executed by the processing and control module 790. The memory 795 may also be capable of storing information collected by the processing system 700, as well as information pertaining to the substrate 140, such as a film thickness map of the surface of the substrate 140. Any conventional memory device capable of the above may be used for the memory 795 of the processing system 700, such as the various devices listed for the memory 180 of FIGS. 1A-1B.

In various embodiments, the illumination system 720 may be capable of forming a spot illumination over a desired localized area of the substrate 140 with a spatial resolution between about 1 µm to about 50 µm. The illumination system 720 can project light at oblique angles on desired locations on the substrate 140 either as a spot or as an optical pattern, which can change in time, including increasing or reducing radiance on the substrate 140 at desired locations as specified. The ability to move the spot illuminated using the incident light beam from the illumination system 720 has the benefit of enabling the processing system 700 to rapidly adjust the processing rate with a high spatial resolution.

The method of delivering optical energy on the substrate 140 in an optical pattern may be combined with other methods of adding or removing materials from the substrate 140, or photomasks, and other items used in semiconductor manufacturing. For example, the processing method for a moving substrate of this disclosure may be combined with wet etch processes. In those embodiments, optical energy can be rapidly delivered to a desired location, and then resulting heat energy may be dissipated into a processing liquid, which may provide pulse-like modification of etch rate at desired locations on the substrate 140.

The steps of the processing method for a moving substrate of this disclosure which traces a raster pattern over the surface of the substrate may be illustrated by the top view of the substrate with the raster pattern superimposed in FIG. 8.

FIG. 8 illustrates a top view of various steps in the forming of a raster pattern superimposed over the substrate 140 in accordance with an embodiment of this disclosure. The substrate of FIG. 8 may be a specific implementation of other substrates described herein such as substrate 140 of FIGS. 1A-1B, for example. The raster pattern illustrated in FIG. 8 may be traced using the processing system 700 for a moving substrate of FIG. 7.

Referring to FIG. 8, a first cycle process 801 illustrates a parallel raster pattern 830 superimposed over a substrate 140 to show how such a pattern might cover the entire substrate 140. The parallel raster pattern 830 includes a series of parallel paths that, in the aggregate, entirely cover the region of the substrate 140 that is to be scanned. Although there is no limitation on the specific pattern that may be used, in some embodiments, the parallel raster pattern 830 is a linear raster pattern including a series of parallel straight (or substantially straight) lines that extend from one side of the substrate 140 to the other as shown. The first cycle process 801 illustrates a first path 850 traced by a processing beam over the substrate 140. During the first path 850, the processing system 700 may be scanning the substrate 140 beneath the processing tool 710 and exposing the surface of the substrate 140 to the processing beam to process the substrate 140. After completing the processing of the first path 850, the optical scanner may illuminate a first spot 851 to heat the surface of the substrate 140 and consequently heat and modify the surface of the substrate 140 exposed to the light in the first spot 851.

After illuminating the first spot 851 for either a preconfigured timeframe, or until the surface of the substrate 140 is determined to reach a preconfigured temperature from the illumination, the optical scanner stops illuminating and the processing system 700 may perform a second cycle process 802. In the second cycle process 802, a second path 852 may be exposed to the processing beam of the processing tool 710 to process along the second path 852 and to process at the modified processing rate the region of the surface of the substrate 140 exposed to the light in the first spot 851. And eventually, the second cycle process 802 may stop the processing beam and use the optical scanner to illuminate a second spot 853. Again, the second spot 853 may heat and consequently modify the processing rate of the surface of the substrate 140 within the second spot 853.

After either reaching the preconfigured temperature (which may be a different temperature than the preconfigured temperature specified for the first spot 851), or after illuminating the second spot 853 for a preconfigured timeframe, the processing system 700 may stop the illuminating using the optical scanner and proceed to a third cycle process 803. In the third cycle process 803, a third path 854 (now moving in the opposite direction of the first path 850 and second path 852 traced using the processing beam) may be exposed to the processing beam of the processing tool 710 to process along the third path 854 and to process at the modified processing rate the region of the surface of the substrate 140 exposed to the light in the second spot 853. And eventually, the third cycle process 803 may stop the processing beam and use the optical scanner to illuminate a third spot 855. Again, the third spot 855 may heat and consequently modify the processing rate of the surface of the substrate 140 within the third spot 855.

An embodiment processing method 804 illustrates an entire sequence of illumination spots 860a-860c which form an optical pattern (illuminated using the optical scanner) and the parallel raster pattern 830 traced over the surface of the substrate 140 using the processing tool 710 and optical scanner of the processing system 700. In the embodiment processing method 804, the processing system 700 may scan while processing until reaching an area of the substrate 140 specified to be processed with an altered processing rate. As a result, the processing system stops scanning and stops the processing beam and begins illuminating the area according to the processing recipe. After the spot reaches the preconfigured temperature desired for modifying the processing rate of that particular area of the substrate 140, the processing tool 710 may begin emitting the processing beam to process the exposed area at the modified processing rate. And that cycle may be repeated as many times as desired for optimizing the processing of the substrate 140 using the processing system 700 for a moving substrate in FIG. 7.

Each section of the parallel raster pattern 830 extending from one side of the substrate 140 to the other may be referred to as a pass 833. The parallel raster pattern 830 may not change direction while over the substrate 140 (as illustrated). This may have the advantage of ensuring very consistent exposure of the substrate 140 during scanning.

For this particular implementation of a parallel raster pattern 830, each consecutive pass of the parallel raster pattern 830 travels the opposite direction as the previous pass. For example, a first pass 831 may be scanned from left to right as shown so that a second pass 832 is scanned from right to left and so on. Although the parallel raster pattern 830 may begin at the end points of the path, it may also begin at any point in the middle (e.g. when scanning half of the substrate 140 at a time which is discussed later on). It should also be noted that the parallel raster pattern 830 may or may not pass directly through a center 805 of the substrate 140 due to the finite (often Gaussian) nature of the processing beam’s or incident light beam’s spot size.

Although the parallel raster pattern 830 is shown and described as covering the entire substrate 140, partial coverage as well as partial processing is also possible. For example, the processing system 700 may be switched off for some portions of the pattern in order to only process certain regions of the substrate 140 and the optical scanner may also turn off for certain portions of the pattern in order to modify processing rates in different regions as specified by the processing recipe. Similarly, parameters of the substrate process (e.g. intensity, duration, etc.) may be changed in real time during scanning to alter processing at various portions of the substrate 140 relative to other portions of the substrate 140. For example, the parameters of the substrate process may be changed in real time based on determinations made using the collection system 730 of the processing system 700. In some cases, a partial raster pattern may be used (e.g. if locations on the substrate 140 specified for processing are grouped together or represent a relatively small fraction of the total substrate area).

The ability to dynamically vary processing parameters while scanning in combination with only scanning portions of a substrate may advantageously allow targeted processing of specific areas of the substrate (e.g. identified as having correctable defects or that are desired to be processed without harming other portions of the substrate, or regions are prescribed to form angled features and other regions of the substrate comprise vertical features, or etcetera). Further, the spatially controllable processing rates controlled by using an optical pattern emitted by the optical scanner of the processing system 700 may further enhance and optimize location specific processing capabilities of conventional scanning processing tools, such as a PPE system. An example processing method which may be implemented in the processing system 700 to perform the processing cycles illustrated using FIG. 8 for forming the parallel raster pattern 830 is described using FIG. 9.

FIG. 9 is a flowchart of a processing method for a moving substrate that uses light to modify/control processing rates over different regions of the surface of the moving substrate in accordance with an embodiment of this disclosure. A method 900 of FIG. 9 may be combined with other methods and performed using the systems and apparatuses for a moving substrate as described herein, such as the processing system 700 of FIG. 7. Although shown in a logical order, the arrangement and numbering of the steps of FIG. 9 are not intended to be limited. The method steps of FIG. 9 may be performed in any suitable order.

Referring to FIG. 9, step 910 of a method 900 of processing a substrate using light to heat and modify/control the processing rate receives a substrate on a substrate holder disposed in a processing chamber. The substrate, the substrate holder, and the processing chamber may be the substrate 140, the substrate holder 150, and the processing chamber 160 of the processing system 700 of FIG. 7 in an embodiment. In an embodiment where the substrate holder is an electrostatic chuck, the receiving of the substrate on the substrate holder may comprise using an electrostatic force of the electrostatic chuck to hold the substrate on the substrate holder during the method 900.

Once the substrate is loaded on the substrate holder within the processing chamber, step 920 of the method 900 scans, using an optical scanner, a raster pattern over a surface of the substrate. The optical scanner illuminates portions of the surface of the substrate as the optical scanner passes over to locally heat the portions according to an optical pattern. For example, in an embodiment, the optical pattern may be the optical pattern 400 described using FIG. 4. As the optical scanner scans over the surface of the substrate, the optical scanner may turn off and turn on light to expose different portions over the surface of the substrate in accordance with what is prescribed by the optical pattern. For example, the optical scanner may traverse a large majority of the surface of the substrate without illuminating and only illuminate regions that would benefit from an altered processing rate due to the heating from the exposure to light.

Still referring to FIG. 9, step 930 of the method 900 scans, using a second scanner, the same raster pattern over the surface of the substrate by following the optical scanner. The second scanner releases materials over the surface of the substrate to process the substrate. For example, step 930 may be releasing a plasma over the surface of the substrate to etch material from the substrate, and regions that were heated using the optical scanner may be etched or processed at a different etch or processing rate than regions that were not heated.

In contrast to the processing systems 100a-100b of FIGS. 1A-1B and the processing system 700 of FIG. 7, other processing systems may use light to modify parameters of the medium used to process the substrate rather than exposing the substrate to an optical pattern. For example, embodiments using a plasma in the processing of the substrate may illuminate regions of the plasma above the substrate to modify plasma parameters of the plasma to control the processing rates over regions of the substrate. FIG. 10 may be used to describe such an embodiment.

FIG. 10 is a schematic diagram of a plasma processing system 1000 capable of modulating plasma parameters of a plasma 1090 disposed over the substrate 140 in accordance with an embodiment of this disclosure. The plasma processing system 1000 comprises the substrate 140 loaded on the substrate holder 150 disposed in a plasma chamber 1060; a first light source 1010 optically coupled to a first window 1015 of the plasma chamber 1060; a second light source 1020 optically coupled to a second window 1025 of the plasma chamber 1060; and a controller 1070 electrically coupled to the plasma chamber 1060, the substrate holder 150, the first light source 1010, the second light source 1020, and a memory 1080. The memory 1080 may store instructions to be executed by the controller 1070 for performing the processing method of this disclosure. Similarly labeled elements may be as previously described.

The plasma chamber 1060 may be any suitable plasma chamber known in the art, such as a plasma etching chamber or a plasma deposition chamber. The first light source 1010 may be any suitable light source known in the art for generating a first plurality of spatially resolved light beams 1030 to illuminate and heat portions of the plasma 1090 over the substrate 140. For example, the first light source 1010 may be a laser, or a source of monochromatic or broadband light that is either collimated or focused into a focused spot in a desired location in space. In various embodiments, the focused spot may be changed over time during processing. Similarly, the second light source 1020 may be any suitable light source known in the art for generating a second plurality of spatially resolved light beams 1040. Again, the second light source 1020 may be a laser, or a source of monochromatic or broadband light that is either collimated or focused into a focused spot in a desired location in space. Again, the focused spot may be changed over time during processing.

The first window 1015 and the second window 1025 may be used to allow the first and second plurality of spatially resolved light beams 1030, 1040 to pass into the plasma chamber 1060 unimpeded. In various embodiments, the first window 1015 and the second window 1025 comprise any suitable material that allows the wavelengths emitted by the first light source 1010 and the second light source 1020 to pass into the plasma chamber 1060, such as glass, quartz, or etcetera. The first light source 1010 and the second light source 1020 may be configured to illuminate the plasma 1090 (as opposed to illuminating the substrate 140 in contrast to processing systems 100a-100b and processing system 700) to heat and modify plasma parameters. As a result, in those embodiments, the first light source 1010 and the second light source 1020 may be configured to emit light beams in a plane parallel to the plane of the surface of the substrate 140 and elevated above the substrate 140.

The plasma 1090 may be any plasma known in the art suitable for processing the substrate 140 according to the processing methods of this disclosure. In an embodiment where the plasma chamber 1060 is a plasma etching chamber, the plasma 1090 may be used to etch material from the substrate 140 using a suitable gas ionized to form the plasma 1090. In an embodiment where the plasma chamber 1060 is a plasma deposition chamber, the plasma 1090 may be used to deposit material over the substrate 140 using a suitable gas ionized to form the plasma 1090.

Still referring to FIG. 10, the controller 1070 may be any device known in the art suitable for controlling the plasma processing system 1000 and implementing the processing method of using optical patterns to heat and modify/control plasma parameters of this disclosure. For example, the controller 1070 may implement plasma processing method 1200 described using FIG. 12. In various embodiments, the controller 1070 may be an application specific integrated circuit (ASIC), a field programmable gate array (FPGA), a microcontroller (MCU), or some form of programmable logic circuit (PLC). And the memory 1080 may be any conventional memory device suitable for storing the instructions for processing the substrate 140 using the plasma processing system 1000 and storing information collected by the plasma processing system 1000. In various embodiments, the memory 1080 may be a solid state drive (SSD), a hard disk drive (HDD), or some form of volatile memory device such as dynamic random access memory (DRAM). An example optical pattern which may be formed in the plasma 1090 is described using FIG. 11.

FIG. 11 illustrates an optical pattern 1100 formed in a plasma over the substrate 140 which may modulate plasma parameters using the plasma processing system 1000 of FIG. 10 in accordance with an embodiment of this disclosure. The optical pattern 1100 may be formed by using the first light source 1010 to emit the first plurality of spatially resolved light beams 1030 and the second light source 1020 to emit the second plurality of spatially resolved light beams 1040 in the plasma above the surface of the substrate 140. And the optical pattern 1100 may alter plasma parameters in overlap regions 1110 which may alter plasma temperature and thus plasma energy density to modify/control processing rates in regions of the substrate 140 exposed to the regions of the plasma with modified plasma parameters.

The overlap regions 1110 may be formed where the first plurality of spatially resolved light beams 1030 and the second plurality of spatially resolved light beams 1040 overlap. In other embodiments, the optical pattern 1100 may be formed by scanning a first light beam emitted from the first light source 1010 and scanning a second light beam emitted from the second light source 1020. And in scanning embodiments, the first light beam and the second light beam may vary corresponding beam properties (such as focus and collimation) during the scanning to form the overlap regions 1110.

In an embodiment, the optical pattern 1100 illustrated in FIG. 11 may be formed in the plasma 1090 of FIG. 10. The optical pattern 1100 is just one example which may be used to modify plasma parameters in the plasma to alter processing rates of the substrate 140 once exposed to the plasma. There are various different optical patterns which may be formed using the first light source 1010 and the second light source 1020. Various different optical patterns may be formed as similarly described for the processing systems 100a-100b of FIGS. 1A-1B. In an embodiment, the plasma processing system 1000 may use the optical pattern 400 of FIG. 4 to modify plasma parameters. Other embodiments may use even more than two light sources to form optical patterns for modifying plasma parameters. An example processing method which may be used to form the optical pattern 1100 of FIG. 11 is described using the flowchart of FIG. 12.

FIG. 12 is a flowchart of a plasma processing method 1200 which may modulate plasma parameters in accordance with an embodiment of this disclosure. The method of FIG. 12 may be combined with other methods and performed using the systems and apparatuses as described herein, such as the plasma processing system 1000 illustrated in FIG. 10. Although shown in a logical order, the arrangement and numbering of the steps of FIG. 12 are not intended to be limiting. The method steps of FIG. 12 may be performed in any suitable order.

Referring to FIG. 12, step 1210 of a plasma processing method 1200 of processing a substrate using light to modify/control the processing rates of material from the substrate receives a substrate on a substrate holder disposed in a processing chamber. For example, the substrate, the substrate holder, and the processing chamber may be the substrate 140, the substrate holder 150, and the plasma chamber 1060 of the plasma processing system 1000 of FIG. 10. The substrate holder may be an electrostatic chuck and may hold the substrate during processing by applying an electrostatic force. And after receiving the substrate on the substrate holder in step 1210, the plasma processing method 1200 may proceed to step 1220. Step 1220 of the plasma processing method 1200 performs a cyclic process to process the substrate.

The cyclic process of step 1220 may start with step 1221 which generates a plasma over a surface of the substrate. In an embodiment, the plasma formed over the surface of the substrate may be the plasma 1090 illustrated in FIG. 10. Once the plasma is formed over the surface of the substrate, the cyclic process (step 1220) of the plasma processing method 1200 proceeds to step 1222. In step 1222, the plasma processing method 1200 applies a first pulse to illuminate, from a first spatially resolved light source and a second spatially resolved light source, an optical pattern in the plasma over the surface of the substrate to modify plasma parameters according to the optical pattern.

In an embodiment, the process described in step 1222 may be performed using the first light source 1010 and second light source 1020 of FIG. 10, and may form the optical pattern 1100 of FIG. 11 either continuously or by a rapid scan of a collimated or focused beam. The optical pattern formed in the plasma may modify plasma parameters in the regions according to the optical pattern formed. Regions exposed to the optical pattern formed by the illuminating of step 1222 may, for example, have modified temperatures, which may make particular regions of the plasma more energetic than the regions not illuminated. As a result, the regions of the plasma with modified plasma parameters may process material from the substrate at different processing rates than regions that were not modified by the illuminating.

Still referring to FIG. 12, the cyclic process (step 1220) may then proceed to step 1223. Step 1223 applies a second pulse to expose the substrate to the plasma to process the substrate with the optical pattern, the first pulse preceding the second pulse. The application of the second pulse may be as described for step 624 of FIG. 6 above, such as the different delays between the starts of the first pulse and second pulse.

The exposure of the substrate to the plasma in step 1223 may be accomplished in various ways. For example, a bias pulse (the second pulse) may be applied to the substrate holder to attract charged particles from the plasma to the substrate for processing. As described above, the regions of the plasma comprising modified plasma parameters in accordance with the optical pattern may process materials from the substrate at different processing rates than regions without modified plasma parameters. As an example, in an embodiment where the plasma processing method 1200 is being used to etch a substrate, modifying plasma parameters of the plasma above the surface of the substrate may increase the temperature of the plasma in those regions, and those regions may remove material (or etch) from the surface of the substrate at a different rate than regions of the plasma that were not modified.

The exposure of the substrate to the plasma in step 1223 may be for a preconfigured timeframe. In other embodiments, the exposure may be until an end point detection (EPD) determines the desired amount of material has been removed from the surface of the substrate. Similarly, the exposure of the plasma to light from the illumination in step 1222 may also be for a preconfigured timeframe, or until a desired plasma parameter is sufficiently adjusted to modify/control the processing rates (such as plasma temperature). After applying the second pulse in step 1223, a single cycle of the cyclic process (step 1220) has completed. The cyclic process (step 1220) may be performed as many times as would be advantageous for fully forming the features prescribed by the processing recipe. For example, various embodiments may perform the cyclic process (step 1220) anywhere from 1 cycle to about 100 cycles.

In other embodiments, rather than immediately transitioning to a new cycle in the cyclic process, the cyclic process (step 1220) may idle a relaxation timeframe for modified plasma parameters to return to equilibrium, and then resume with step 1221. The method 1200 may perform as many cycles of the cyclic process as desired in order to fully process the substrate.

Example embodiments of the invention are described below. Other embodiments can also be understood from the entirety of the specification as well as the claims filed herein.

Example 1. A method for processing a substrate includes receiving the substrate on a substrate holder disposed in a processing chamber, and performing a cyclic process. One cycle of the cyclic process includes applying a first pulse to illuminate, from an optical source, an optical pattern over a surface of the substrate to locally heat portions of the surface of the substrate according to the optical pattern. And one cycle of the cyclic process further includes applying a second pulse to generate a processing beam to process the substrate with the optical pattern, the first pulse preceding the second pulse.

Example 2. The method of example 1, where the second pulse starts after the first pulse ends.

Example 3. The method of one of examples 1 or 2, where the first pulse and the second pulse overlap.

Example 4. The method of one of examples 1 to 3, where the processing beam includes a neutral flux, a gas cluster flux, an ion flux, or a plasma flux.

Example 5. The method of one of examples 1 to 4, where the processing beam etches materials from the substrate according to the optical pattern.

Example 6. The method of one of examples 1 to 5, where the processing beam deposits materials over the surface of the substrate according to the optical pattern.

Example 7. The method of one of examples 1 to 6, where applying the first pulse to illuminate, from the optical source, the optical pattern over the surface of the substrate to locally heat portions of the surface of the substrate changes an etch rate of materials in the portions.

Example 8. The method of one of examples 1 to 7, where applying the first pulse to illuminate, from the optical source, the optical pattern over the surface of the substrate to locally heat portions of the surface of the substrate changes a deposition rate of materials in the portions.

Example 9. The method of one of examples 1 to 8, where the optical pattern includes a heat distribution map.

Example 10. A method for processing a substrate includes receiving the substrate on a substrate holder disposed in a processing chamber, and scanning, using an optical scanner, a raster pattern over a surface of the substrate, the optical scanner illuminating portions of the surface of the substrate as the optical scanner passes over to locally heat the portions according to an optical pattern. And the method further includes scanning, using a second scanner, the raster pattern over the surface of the substrate by following the optical scanner, the second scanner releasing materials over the surface of the substrate to process the substrate.

Example 11. The method of example 10, where the materials released by the second scanner over the surface of the substrate etch the substrate, and locally heating the portions according to the optical pattern changes an etch rate of the portions of the surface of the substrate.

Example 12. The method of one of examples 10 or 11, where the materials released by the second scanner over the surface of the substrate deposit over the substrate, and locally heating the portions according to the optical pattern changes a deposition rate of the portions of the surface of the substrate.

Example 13. A system for processing a substrate includes a substrate holder disposed in a processing chamber, and an optical source optically coupled to the processing chamber. And the system further includes a controller coupled to the optical source, the substrate holder, the processing chamber, and a memory storing instructions to be executed in the controller. The instructions when executed cause the controller to receive the substrate on the substrate holder disposed in the processing chamber, and perform a cyclic process. One cycle of the cyclic process includes applying a first pulse to illuminate, from the optical source, an optical pattern over a surface of the substrate to locally heat portions of the surface of the substrate according to the optical pattern. And one cycle of the cyclic process further includes applying a second pulse to generate a processing beam to process the substrate with the optical pattern, the first pulse preceding the second pulse.

Example 14. The system of example 13, where the optical source includes a first spatially resolved light source and a second spatially resolved light source.

Example 15. The system of one of examples 13 or 14, further including a chamber cover disposed between the substrate holder and the optical source, the chamber cover sealing the processing chamber.

Example 16. The system of one of examples 13 to 15, where the chamber cover includes a gas shower head including holes intermixed with light-transparent areas.

Example 17. The system of one of examples 13 to 16, where the optical source includes an illuminator optically coupled to a projection lens, and the optical pattern includes a heat distribution map generated from a film thickness map of the substrate.

Example 18. The system of one of examples 13 to 17, where the applying the first pulse to illuminate, from the optical source, the optical pattern over the surface of the substrate includes emitting, using the illuminator, light through the projection lens to form a projected pattern. And applying the first pulse to illuminate further includes projecting, using the projection lens, the projected pattern through the chamber cover to form the optical pattern over the surface of the substrate.

Example 19. The system of one of examples 13 to 18, where the optical source includes a ring illuminator, and the optical pattern includes a ring of light around outer edges of the surface of the substrate.

Example 20. The system of one of examples 13 to 19, where the applying the first pulse to illuminate, from the optical source, the optical pattern over the surface of the substrate includes emitting, using the ring illuminator, light through the chamber cover to form the optical pattern over the surface of the substrate.

Example 21. A method for processing a substrate includes receiving the substrate on a substrate holder disposed in a processing chamber, and performing a cyclic process. One cycle of the cyclic process includes generating a plasma over a surface of the substrate, applying a first pulse to illuminate, from a first spatially resolved light source and a second spatially resolved light source, an optical pattern in the plasma over the surface of the substrate to modify plasma parameters according to the optical pattern. And one cycle of the cyclic process further includes applying a second pulse to expose the substrate to the plasma to process the substrate with the optical pattern, the first pulse preceding the second pulse.

Example 22. A system for processing a substrate includes a substrate holder disposed in a processing chamber, a first spatially resolved light source optically coupled to the processing chamber and a second spatially resolved light source optically coupled to the processing chamber. And the system further includes a controller coupled to the first spatially resolved light source, the second spatially resolved light source, the substrate holder, the processing chamber, and a memory storing instructions to be executed in the controller. The instructions when executed cause the controller to receive the substrate on the substrate holder disposed in the processing chamber, and perform a cyclic process. One cycle of the cyclic process includes generating a plasma over a surface of the substrate, and applying a first pulse to illuminate, from the first spatially resolved light source and the second spatially resolved light source, an optical pattern in the plasma over the surface of the substrate to modify plasma parameters according to the optical pattern. And one cycle of the cyclic process further includes applying a second pulse to expose the substrate to the plasma to process the substrate with the optical pattern, the first pulse preceding the second pulse.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for processing a substrate, the method comprising:
receiving the substrate on a substrate holder disposed in a processing chamber; and
performing a cyclic process, one cycle of the cyclic process comprising:
applying a first pulse to illuminate, from an optical source, an optical pattern over a surface of the substrate to locally heat portions of the surface of the substrate according to the optical pattern; and
applying a second pulse to generate a processing beam to process the substrate with the optical pattern, the first pulse preceding the second pulse.

2. The method of claim 1, wherein the second pulse starts after the first pulse ends.

3. The method of claim 1, wherein the first pulse and the second pulse overlap.

4. The method of claim 1, wherein the processing beam comprises a neutral flux, a gas cluster flux, an ion flux, or a plasma flux.

5. The method of claim 1, wherein the processing beam etches materials from the substrate according to the optical pattern.

6. The method of claim 1, wherein the processing beam deposits materials over the surface of the substrate according to the optical pattern.

7. The method of claim 1, wherein applying the first pulse to illuminate, from the optical source, the optical pattern over the surface of the substrate to locally heat portions of the surface of the substrate changes an etch rate of materials in the portions.

8. The method of claim 1, wherein applying the first pulse to illuminate, from the optical source, the optical pattern over the surface of the substrate to locally heat portions of the surface of the substrate changes a deposition rate of materials in the portions.

9. The method of claim 1, wherein the optical pattern comprises a heat distribution map.

10. A method for processing a substrate, the method comprising:
receiving the substrate on a substrate holder disposed in a processing chamber;
scanning, using an optical scanner, a raster pattern over a surface of the substrate, the optical scanner illuminating portions of the surface of the substrate as the optical scanner passes over to locally heat the portions according to an optical pattern; and
scanning, using a second scanner, the raster pattern over the surface of the substrate by following the optical scanner, the second scanner releasing materials over the surface of the substrate to process the substrate.

11. The method of claim 10, wherein the materials released by the second scanner over the surface of the substrate etch the substrate, and locally heating the portions according to the optical pattern changes an etch rate of the portions of the surface of the substrate.

12. The method of claim 10, wherein the materials released by the second scanner over the surface of the substrate deposit over the substrate, and locally heating the portions according to the optical pattern changes a deposition rate of the portions of the surface of the substrate.

13. A system for processing a substrate, the system comprising:
a substrate holder disposed in a processing chamber;
an optical source optically coupled to the processing chamber; and
a controller coupled to the optical source, the substrate holder, the processing chamber, and a memory storing instructions to be executed in the controller, the instructions when executed cause the controller to:
receive the substrate on the substrate holder disposed in the processing chamber; and
perform a cyclic process, one cycle of the cyclic process comprising:
applying a first pulse to illuminate, from the optical source, an optical pattern over a surface of the substrate to locally heat portions of the surface of the substrate according to the optical pattern; and
applying a second pulse to generate a processing beam to process the substrate with the optical pattern, the first pulse preceding the second pulse.

14. The system of claim 13, wherein the optical source comprises a first spatially resolved light source and a second spatially resolved light source.

15. The system of claim 13, further comprising a chamber cover disposed between the substrate holder and the optical source, the chamber cover sealing the processing chamber.

16. The system of claim 15, wherein the chamber cover comprises a gas shower head comprising holes intermixed with light-transparent areas.

17. The system of claim 15, wherein the optical source comprises an illuminator optically coupled to a projection lens, and the optical pattern comprises a heat distribution map generated from a film thickness map of the substrate.

18. The system of claim 17, wherein the applying the first pulse to illuminate, from the optical source, the optical pattern over the surface of the substrate comprises:
emitting, using the illuminator, light through the projection lens to form a projected pattern; and
projecting, using the projection lens, the projected pattern through the chamber cover to form the optical pattern over the surface of the substrate.

19. The system of claim 15, wherein the optical source comprises a ring illuminator, and the optical pattern comprises a ring of light around outer edges of the surface of the substrate.

20. The system of claim 19, wherein the applying the first pulse to illuminate, from the optical source, the optical pattern over the surface of the substrate comprises emitting, using the ring illuminator, light through the chamber cover to form the optical pattern over the surface of the substrate.
